(19) United States
(12) Patent Application Publication
(10) Pub. No.: US 2012/0223435 A1
(43) Pub. Date: Sep. 6, 2012

(54) INTEGRATED CIRCUIT PACKAGING SYSTEM WITH LEADS AND METHOD OF MANUFACTURE THEREOF

(76) Inventors: A Leam Choi, Ichon-si (KR); Jae Han Chung, Ichon-si (KR); DeokKyung Yang, Hanam-si (KR)

(21) Appl. No.: 13/038,384

(22) Filed: Mar. 1, 2011

(51) Int. Cl. H01L 23/48; H01L 21/56

(52) U.S. Cl. 257/773; 438/124; 257/E21.502; 257/E23.01

(57) ABSTRACT

A method of manufacture of an integrated circuit packaging system includes: forming a base package having a base integrated circuit over a base substrate; stacking a mountable device over the base package with a flow channel between the mountable device and the base package; and forming an external lead having a lead platform and a lead leg, the lead platform extending from the mountable device and the lead leg parallel to the base package.

### TECHNICAL FIELD

The present invention relates generally to an integrated circuit packaging system, and more particularly to a system for an integrated circuit packaging system with leads.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made using the semiconductor package structures. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Many conventional semiconductor (or “chip”) packages are of the type where a semiconductor die is molded into a package with a resin, such as an epoxy molding compound. Numerous package approaches stack multiple integrated circuit dice or package in package (PIP) or a combination. Other approaches include package level stacking or package-on-package (POP). POP designs face reliability challenges and higher cost.

Thus, a need still remains for an integrated circuit system improved yield, low profile, and improved reliability. In view of the ever-increasing commercial competitive pressures, along with growing consumer expectations and the diminishing opportunities for meaningful product differentiation in the marketplace, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: forming a base package having a base integrated circuit over a base substrate; stacking a mountable device over the base package with a flow channel between the mountable device and the base package; and forming an external lead having a lead platform and a lead leg, the lead platform extending from the mountable device and the lead leg parallel to the base package.

The present invention provides an integrated circuit packaging system, including: a base package having a base integrated circuit over a base substrate; a mountable device stacked over the base package with a flow channel between the mountable device and the base package; and an external lead having a lead platform and a lead leg, the lead platform extending from the mountable device and the lead leg parallel to the base package.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-section view of the integrated circuit packaging system along line 2-2 of FIG. 1.

FIG. 3 is a cross-section view of an integrated circuit packaging system exemplified along line 2-2 of FIG. 1 in a second embodiment of the present invention.

FIG. 4 is a cross-section view of an integrated circuit packaging system exemplified along line 2-2 of FIG. 1 in a third embodiment of the present invention.

FIG. 5 is a top view of an integrated circuit packaging system in a fourth embodiment of the present invention.

FIG. 6 is a cross-section view of the integrated circuit packaging system along line 6-6 of FIG. 5.

FIG. 7 is a top view of an integrated circuit package-on-package system in a fifth embodiment of the present invention.

FIG. 8 is a cross-section view of the integrated circuit package-on-package system along line 8-8 of FIG. 7.

FIG. 9 is a flow chart of a method of manufacture of an integrated circuit packaging system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements.

The term “processing” as used herein includes deposition of material or photoresist, patterning, exposure, development, etching, cleaning, and/or removal of the material or photoresist as required in forming a described structure.

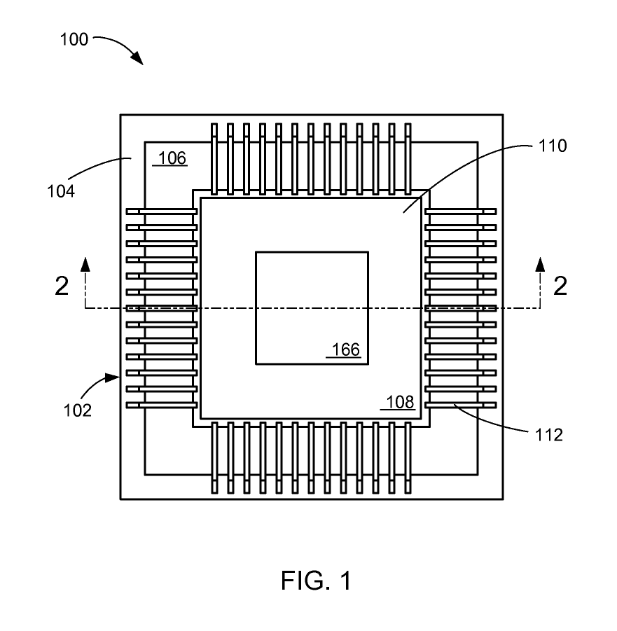

Referring now to FIG. 1, therein is shown a top view of an integrated circuit packaging system 100 in a first embodiment of the present invention. The top view depicts a base package 102. The base package 102 is an integrated circuit package having a side with a recessed interface to receive a matching conformal mating interface of another integrated circuit package. Conformal means that the mating interface of the another integrated circuit package is parallel with the recessed interface.

The base package 102 can include a base substrate 104. The base substrate 104 is a rigid base structure that provides support and connectivity for other components and devices. As an example, the base substrate 104 can be made from conductive material, such as copper or other metals, ceramic material, semi-conducting material, such as silicon, a laminated structure having vias and metal layers (not shown), or a combination thereof.

The base package 102 can include a base encapsulation 106. The base encapsulation 106 is a cover, such as a protective covering. As an example, the base encapsulation 106 can be formed by molding an encapsulation material such as epoxy molding compound or ceramic material.

The base encapsulation 106 can be over the base substrate 104. The base encapsulation 106 can cover a central portion of the base substrate 104. The base encapsulation 106 can expose a peripheral region of the base substrate 104 along the perimeter of the base substrate 104.

A mountable device 108 can be stacked over the base package 102. The mountable device 108 is an integrated circuit package having a side with a mating interface to fit within and is conformal with a recess of another integrated circuit package. The mountable device 108 can be over a central portion of the base encapsulation 106. The mountable device 108 stacked over the base package 102 can form a package-on-package system.

The mountable device 108 can have a mountable encapsulation 110. The mountable encapsulation 110 is a cover, such as a protective covering. As an example, the mountable encapsulation 110 can be formed by molding an encapsulation material such as epoxy molding compound or ceramic material.

A mountable paddle 166 can be exposed from the mountable encapsulation 110. The mountable paddle 166 is a structure for mounting a device, such as an integrated circuit device. As an example, the mountable paddle 166 can be a die paddle, a die attach paddle, a heat sink, or a combination thereof. The mountable paddle 166 can be made from a number of materials, including conductive materials, such as copper, a copper based alloy, other metallic alloys, or other conductive materials.

The mountable device 108 can have external leads 112. The external leads 112 are conductive connectors for electrically connecting the mountable device 108 to other devices or structures and also to provide structural support for suspension of the mountable device 108 over other devices or structures. The external leads 112 can be exposed from and extend away from the mountable encapsulation 110.

The external leads 112 can extend over the base encapsulation 106 and connect with the base substrate 104. The external leads 112 can be connected with the base substrate 104 at the peripheral portion along the perimeter of the base substrate 104 that is not covered by the base encapsulation 106.

For illustrative purposes, the integrated circuit packaging system 100 is shown with the external leads 112 along four sides of the mountable device 108, although it is understood that the integrated circuit packaging system 100 can have the external leads 112 arranged differently. For example, the external leads 112 can be only along two opposing sides of the mountable device 108.

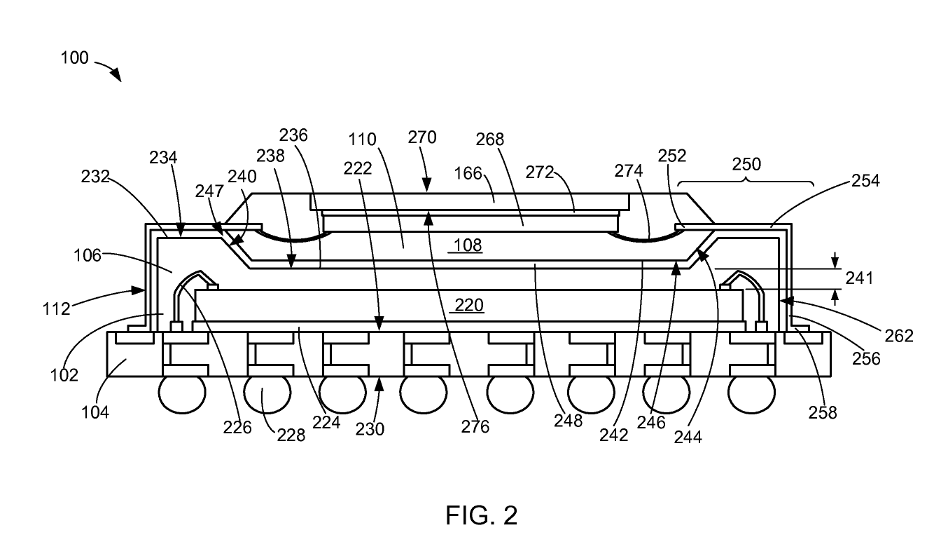

Referring now to FIG. 2, therein is shown a cross-sectional view of the integrated circuit packaging system 100 along line 2-2 of FIG. 1. The cross-sectional view depicts a base integrated circuit 220 mounted over the base substrate 104. The base integrated circuit 220 is a semi-conductor device having active circuitry fabricated thereto. As an example, the base integrated circuit 220 can be an integrated circuit die, a thin integrated circuit die, an ultrathin integrated circuit die, or a wire-bonded integrated circuit die. The base integrated circuit 220 can be mounted over a substrate first side 222 of the base substrate 104.

A base adhesive 224 can be over the substrate first side 222 and the base integrated circuit 220 can be over the base adhesive 224. The base adhesive 224 is an adhesive material for bonding components. As an example, the base adhesive 224 can be a thermally conductive adhesive material, a polymer based adhesive material, or any other adhesive material suitable for bonding components.

Base internal interconnects 226 can connect the base integrated circuit 220 and the substrate first side 222. The base internal interconnects 226 are conductive interconnects for electrical interconnection of devices and structures. As an example, the base internal interconnects 226 can be bond wires or ribbon bond wires. The base internal interconnects 226 can be connected to the side of the base integrated circuit 220 facing away from the substrate first side 222.

Base external interconnects 228 can be connected to a substrate second side 230 of the base substrate 104. The base external interconnects 228 are conductive interconnects for connecting the base substrate 104 to the next system level down (not shown). As an example, the base external interconnects 228 can be solder balls, solder bumps, or conductive bumps. The substrate second side 230 can be the side of the base substrate 104 facing away from the base integrated circuit 220.

The base encapsulation 106 can be over and cover the central portion of the substrate first side 222. The base encapsulation 106 can expose the peripheral region of the base substrate 104 along the perimeter of the base substrate 104. The base encapsulation 106 can cover the base integrated circuit 220, the base adhesive 224, and the base internal interconnects 226.

The base encapsulation 106 can include a base shoulder 232 along a base top side 234 of the base encapsulation 106. As a specific example, the portion of the base shoulder 232 along the base top side 234 can have a width of 0.5 millimeters. The base shoulder 232 can be over the base internal interconnects 226. The base shoulder 232 can provide clearance for the base internal interconnects 226 to connect between the substrate first side 222 and the base integrated circuit 220.

The base encapsulation 106 can include a base recess 236 having a recessed surface 238 and a recess side 240. The base recess 236 can be shaped to receive a mating interface of another integrated circuit package.

The base recess 236 can be formed along a central portion of the base top side 234. The base recess 236 can be bounded by the base shoulder 232. The recessed surface 238 can be over the base integrated circuit 220. The horizontal plane of the recessed surface 238 can be below the horizontal plane of the base shoulder 232.

The recess side 240 can be between the recessed surface 238 and the base shoulder 232. The recess side 240 can be sloped and can form an obtuse angle with the recessed surface 238. The recess side 240 can be sloped downward from the base shoulder 232 to the recessed surface 238.

The base encapsulation 106 can include a recess thickness 241, which is measured as the distance between the recessed surface 238 and the side of the base integrated circuit 220 facing away from the substrate first side 222. As a specific example, the recess thickness 241 can have a distance of 150 μm.

The mountable device 108 can be stacked over the base package 102 with a mountable mating interface 242 of the mountable encapsulation 110 in the base recess 236. The mountable mating interface 242 is a surface of the mountable encapsulation 110 configured to fit within and is conformal with a space having matching surface features. The mountable mating interface 242 can be the side of the mountable encapsulation 110 facing the base top side 234 of the base encapsulation 106. The mountable device 108 stacked over the base package 102 can form a package-on-package system.

The mountable mating interface 242 can be conformal with the base recess 236. The mountable mating interface 242 can have a mating side 244 that faces and is parallel to the recess side 240. A mating bottom 246 can be the side of the mountable mating interface 242 that faces and is parallel to the recessed surface 238 of the base recess 236. The mountable mating interface 242 can be conformal with the base recess 236 by having the mating side 244 parallel to the recess side 240 and the mating bottom 246 parallel to the recessed surface 238.

The mountable mating interface 242 can be configured to provide a flow channel 248 between the base recess 236 of the base encapsulation 106 and the mountable mating interface 242. The flow channel 248 is a channel for the circulation of air, which can facilitate temperature control for the interface between the mountable device 108 and the base package 102.

The flow channel 248 can extend from a flow opening 247 between the recess side 240 and the mating side 244, through the space between the mating bottom 246 and the recessed surface 238, to another one of the opening between the recess side 240 and the mating side 244 at the opposite end of the flow channel 248.

The mountable device 108 can include an interconnect structure 250. The interconnect structure 250 is a partially encapsulated conductive structure for providing electrical connection between internal package components and external components and devices. The interconnect structure 250 is also for providing structural support for suspending a package over other devices or components. As an example, the interconnect structure 250 can be a rigid lead made from conductive materials, such as copper, a copper based alloy, other metallic alloys, or other conductive materials.

The interconnect structure 250 can include internal leads 252 and the external leads 112. The internal leads 252 are the portion of the interconnect structure 250 that is encapsulated by the mountable encapsulation 110.

The external leads 112 can be exposed from and extend from the mountable encapsulation 110. The external leads 112 can include a lead platform 254, a lead leg 256, and a lead foot 258. The lead platform 254 is the portion of the external leads 112 that is adjacent to the mountable encapsulation 110 and over the base top side 234 of the base encapsulation 106.

As an example, the lead platform 254 can be parallel with the base shoulder 232, although it is understood that the lead platform 254 may be in a configuration that is not parallel with the base shoulder 232.

The lead platform 254 can extend away from the mountable encapsulation 110. The lead platform 254 can extend beyond a base vertical side 262 of the base package 102. The base vertical side 262 is a vertical side of the base package 102. As a specific example, the base vertical side 262 can be the vertical side of the base encapsulation 106.

The external leads 112 can be bent at the end of the lead platform 254 that is opposite the mountable encapsulation 110 to form the lead leg 256. The lead leg 256 is the portion of the external leads 112 that is adjacent to the base vertical side 262.

As an example, the lead leg 256 can be perpendicular with the lead platform 254 and extend towards the substrate first side 222. As a further example, the lead leg 256 can be parallel with the base vertical side 262. In yet a further example, the lead leg 256 can be perpendicular to the substrate first side 222.

The external leads 112 can be bent at the end of the lead leg 256 opposite the lead platform 254 and adjacent to the substrate first side 222 to form the lead foot 258. The lead foot 258 can extend away from the base vertical side 262. The lead foot 258 can be planar with and connected to the substrate first side 222.

The mountable device 108 can include the mountable paddle 166 having a paddle first side 270 and a paddle second side 276. The paddle first side 270 can be exposed along the side of the mountable encapsulation 110 facing away from the base package 102. The paddle first side 270 can be co-planar with the side of the mountable encapsulation 110 facing away from the base package 102.

A mountable integrated circuit 268 can be mounted on the paddle second side 276 of the mountable paddle 166. The mountable integrated circuit 268 is a semi-conductor device having active circuitry fabricated thereto. As an example, the base integrated circuit 220 can be an integrated circuit die, a thin integrated circuit die, an ultrathin integrated circuit die, a wire-bonded integrated circuit die, or a flip chip.

A mountable adhesive 272, which is an adhesive material for bonding components, can be on the paddle second side 276 and the mountable integrated circuit 268 can be on the mountable adhesive 272. As an example, the mountable adhesive 272 can be a thermally conductive adhesive material, a polymer based adhesive material, or any other adhesive material suitable for bonding components.

Mountable internal interconnects 274 can connect the mountable integrated circuit 268 and the internal leads 252. The mountable internal interconnects 274 are conductive interconnects for electrical interconnection of devices and structures. As an example, the base internal interconnects 226 can be bond wires or ribbon bond wires.

It has been discovered that the present invention provides the integrated circuit packaging system 100 a reduced area when mounting over a secondary structure. The lead legs 256 perpendicular with the lead platforms 254 and parallel with the base vertical side 262 reduces the space required for stacking the mountable device 108 over the base package 102. Furthermore, the controlled tolerance and spacing of the inner leg distance 270 also reduces the space required for stacking the mountable device 108 over the base package 102.

It has been further discovered that the present invention provides the integrated circuit packaging system 100 having reduced overall package height. The base recess 236 provides a conformal space for the mountable device 108 to achieve a lower profile while still providing a protective cover for the base internal interconnects 226. Further, conventional molding methods can be used to form the base encapsulation 106, thereby reducing overall cost for the formation of a low profile for the integrated circuit packaging system 100.

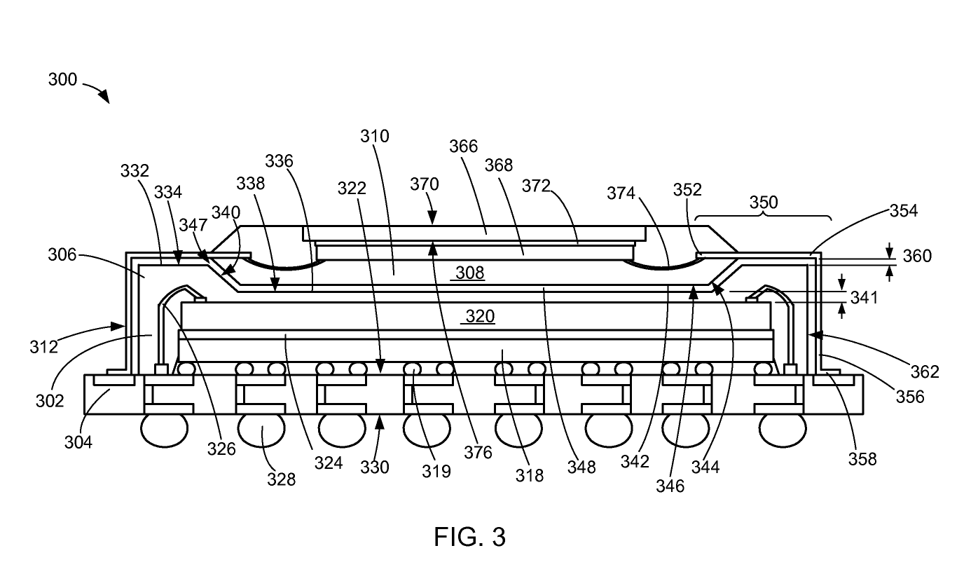

Referring now to FIG. 3, therein is shown a cross-sectional view of an integrated circuit packaging system 300 exemplified along line 2-2 of FIG. 1 in a second embodiment of the present invention. The cross-sectional view depicts a base package 302. The base package 302 is an integrated circuit package having a side with a recessed interface to receive a matching conformal mating interface of another integrated circuit package. Conformal means that the mating interface of the another integrated circuit package is parallel with the recessed interface.

The base package 302 can include a base substrate 304. The base substrate 304 is a rigid base structure that provides support and connectivity for other components and devices. As an example, the base substrate 304 can be made from conductive material, such as copper or other metals, ceramic material, semi-conducting material, such as silicon, or can be a laminated structure having vias and metal layers (not shown).

A base circuit device 318 can be mounted over a substrate first side 322 of the base substrate 304. The base circuit device 318 is a semi-conductor device having active circuitry fabricated thereto. As an example, the base circuit device 318 can be a flip chip, an integrated circuit die, a thin integrated circuit die, or an ultrathin integrated circuit die.

The base circuit device 318 can be connected to the substrate first side 322 with circuit device connectors 319. The circuit device connectors 319 are conductive interconnects for electrical interconnection of devices and structures. As an example, the circuit device connectors 319 can be solder balls, solder bumps, or connective bumps. The circuit device connectors 319 can be connected between the substrate first side and the side of the base circuit device 318 facing the substrate first side 322.

A base integrated circuit 320 can be mounted over the base circuit device 318. The base integrated circuit 320 is a semi-conductor device having active circuitry fabricated thereto. As an example, the base integrated circuit 320 can be an integrated circuit die, a thin integrated circuit die, an ultrathin integrated circuit die, or a wire-bonded integrated circuit die. The base integrated circuit 320 can be mounted over the base circuit device 318 facing away from the substrate first side 322.

A base adhesive 324 can be over the base circuit device 318 and the base integrated circuit 320 can be over the base adhesive 324. The base adhesive 324 is an adhesive material for bonding components. As an example, the base adhesive 324 can be a thermally conductive adhesive material, a polymer based adhesive material, or any other adhesive material suitable for bonding components.

Base internal interconnects 326 can connect the base integrated circuit 320 and the substrate first side 322. The base internal interconnects 326 are conductive interconnects for electrical interconnection of devices and structures. As an example, the base internal interconnects 326 can be bond wires or ribbon bond wires. The base internal interconnects 326 can be connected to the side of the base integrated circuit 320 facing away from the substrate first side 322.

Base external interconnects 328 can be connected to a substrate second side 330 of the base substrate. The base external interconnects 328 are conductive interconnects for connecting the base substrate 304 to the next system level down (not shown). As an example, the base external interconnects 328 can be solder balls, solder bumps, or conductive bumps. The substrate second side 330 can be the side of the base substrate 304 facing away from the base integrated circuit 320.

A base encapsulation 306 can be over and cover the central portion of the substrate first side 322. The base encapsulation 306 is a cover, such as a protective covering. As an example, the base encapsulation 306 can be formed by molding an encapsulation material such as epoxy molding compound or ceramic material.

The base encapsulation 306 can expose the peripheral region of the base substrate 304 along the perimeter of the base substrate 304. The base encapsulation 306 can cover the base integrated circuit 320, the base adhesive 324, and the base internal interconnects 326.

The base encapsulation 306 can include a base shoulder 332 along a base top side 334 of the base encapsulation 306. As a specific example, the portion of the base shoulder 332 along the base top side 334 can have a width of 0.5 millimeters. The base shoulder 332 can be over the base internal interconnects 326. The base shoulder 332 can provide clearance for the base internal interconnects 326 to connect between the substrate first side 322 and the base integrated circuit 320.

The base encapsulation 306 includes a base recess 336 having a recessed surface 338 and a recess side 340. The base recess 336 can be shaped to receive a mating interface of another integrated circuit package.

The base recess 336 can be formed along a central portion of the base top side 334. The base recess 336 can be bounded by the base shoulder 332. The recessed surface 338 can be over the base integrated circuit 320. The horizontal plane of the recessed surface 338 can be below the horizontal plane of the base shoulder 332.

The recess side 340 can be between the recessed surface 338 and the base shoulder 332. The recess side 340 can be sloped and can form an obtuse angle with the recessed surface 338.

The base encapsulation 306 can include a recess thickness 341, which is measured as the distance between the recessed surface 338 and the side of the base integrated circuit 320 facing away from the substrate first side 322. As a specific example, the recess thickness 341 can have a distance of 150 μm.

A mountable device 308 can be stacked over the base package 302. The mountable device 308 is an integrated circuit package having a side with a mating interface to fit within and is conformal with a recess of another integrated circuit package. The mountable device 108 can be over a central portion of the base encapsulation 306. The mountable device 308 stacked over the base package 302 can form a package-on-package system.

The mountable device 308 can include a mountable encapsulation 310 having a mountable mating interface 342. The mountable encapsulation 310 is a cover, such as a protective covering. As an example, the mountable encapsulation 310 can be formed by molding an encapsulation material such as epoxy molding compound or ceramic material.

The mountable mating interface 342 is a surface of the mountable encapsulation 310 configured to fit within a space having matching surface features. The mountable mating interface 342 can be the side of the mountable encapsulation 310 facing the base top side 334 of the base encapsulation 306. The mountable mating interface 342 of the mountable encapsulation 310 can be in the base recess 336.

The mountable mating interface 342 can be conformal with the base recess 336. The mountable mating interface 342 can have a mating side 344 that faces and is parallel to the recess side 340. A mating bottom 346 can be the side of the mountable mating interface 342 that faces and is parallel to the recessed surface 338 of the base recess 336. The mountable mating interface 342 can be conformal with the base recess 336 by having the mating side 344 parallel to the recess side 340 and the mating bottom 346 parallel to the recessed surface 338.

The mountable mating interface 342 can be configured to provide a flow channel 348 between the base recess 336 of the base encapsulation 306 and the mountable mating interface 342. The flow channel 348 is a channel for the circulation of air, which can facilitate temperature control for the interface between the mountable device 308 and the base package 302.

The flow channel 348 can extend from a flow opening 347 between the recess side 340 and the mating side 344, through the space between the mating bottom 346 and the recessed surface 338, to another one of the opening between the recess side 340 and the mating side 344 at the opposite end of the flow channel 348.

The mountable device 308 can include an interconnect structure 350. The interconnect structure 350 is a partially encapsulated conductive structure for providing electrical connection between internal package components and external components and devices. The interconnect structure 350 is also for providing structural support for suspending a package over other devices or components. As an example, the interconnect structure 350 can be a rigid lead made from conductive materials, such as copper, a copper based alloy, other metallic alloys, or other conductive materials.

The interconnect structure 350 can include internal leads 352 and external leads 312. The internal leads 352 are the portion of the interconnect structure 350 that is encapsulated by the mountable encapsulation 310.

The external leads 312 are conductive connectors for electrically connecting the mountable device 308 to other devices or structures and also to provide structural support for suspension of the mountable device 308 over other devices or structures. The external leads 312 can be exposed from and extend away from the mountable encapsulation 310.

The external leads 312 can be exposed from and extend from the mountable encapsulation 310. The external leads 312 can include a lead platform 354, a lead leg 356, and a lead foot 358. The lead platform 354 is the portion of the external leads 312 that is adjacent to the mountable encapsulation 310 and over the base top side 334 of the base encapsulation 306.

As an example, the lead platform 354 can be parallel with the portion of the base top side 334 that is around the base recess 336, although it is understood that the lead platform 354 may be in a configuration that is not parallel with the base top side 334.

The lead platform 354 can extend away from the mountable encapsulation 310. The lead platform 354 can extend beyond a base vertical side 362 of the base package 302. The base vertical side 362 is a vertical side of the base package 302. As a specific example, the base vertical side 362 can be the vertical side of the base encapsulation 306.

The external leads 312 can be bent at the end of the lead platform 354 that is opposite the mountable encapsulation 310 to form the lead leg 356. The lead leg 356 is the portion of the external leads 312 that is adjacent to the base vertical side 362.

As an example, the lead leg 356 can be perpendicular with the lead platform 354 and extend towards the substrate first side 322. As a further example, the lead leg 356 can be parallel with the base vertical side 262. In yet a further example, the lead leg 356 can be perpendicular to the substrate first side 322.

The external leads 312 can be bent at the end of the lead leg 356 opposite the lead platform 354 and adjacent to the substrate first side 322 to form the lead foot 358. The lead foot 358 can extend away from the base vertical side 362. The lead foot 358 can be planar with and connected to the substrate first side 322.

The mountable device 308 can include a mountable paddle 366, which is a structure for mounting a device, such as an integrated circuit device. As an example, the mountable paddle 366 can be a die paddle, a die attach paddle, a heat sink, or a combination thereof. The mountable paddle 366 can be made from a number of materials, including conductive materials, such as copper, a copper based alloy, other metallic alloys, or other conductive materials.

The mountable paddle 366 can include a paddle first side 370 and a paddle second side 376. The paddle first side 370 can be exposed along the side of the mountable encapsulation 310 facing away from the base package 302. The paddle first side 370 can be co-planar with the side of the mountable encapsulation 310 facing away from the base package 302.

A mountable integrated circuit 368 can be mounted on the paddle second side 376 of the mountable paddle 366. The mountable integrated circuit 368 is a semi-conductor device having active circuitry fabricated thereto. As an example, the base integrated circuit 320 can be an integrated circuit die, a thin integrated circuit die, an ultrathin integrated circuit die, a wire-bonded integrated circuit die, or a flip chip.

A mountable adhesive 372, which is an adhesive material for bonding components, can be on the paddle second side 376 and the mountable integrated circuit 368 can be on the mountable adhesive 372. As an example, the mountable adhesive 372 can be a thermally conductive adhesive material, a polymer based adhesive material, or any other adhesive material suitable for bonding components.

Mountable internal interconnects 374 can connect the mountable integrated circuit 368 and the internal leads 352. The mountable internal interconnects 374 are conductive interconnects for electrical interconnection of devices and structures. As an example, the base internal interconnects 326 can be bond wires or ribbon bond wires.

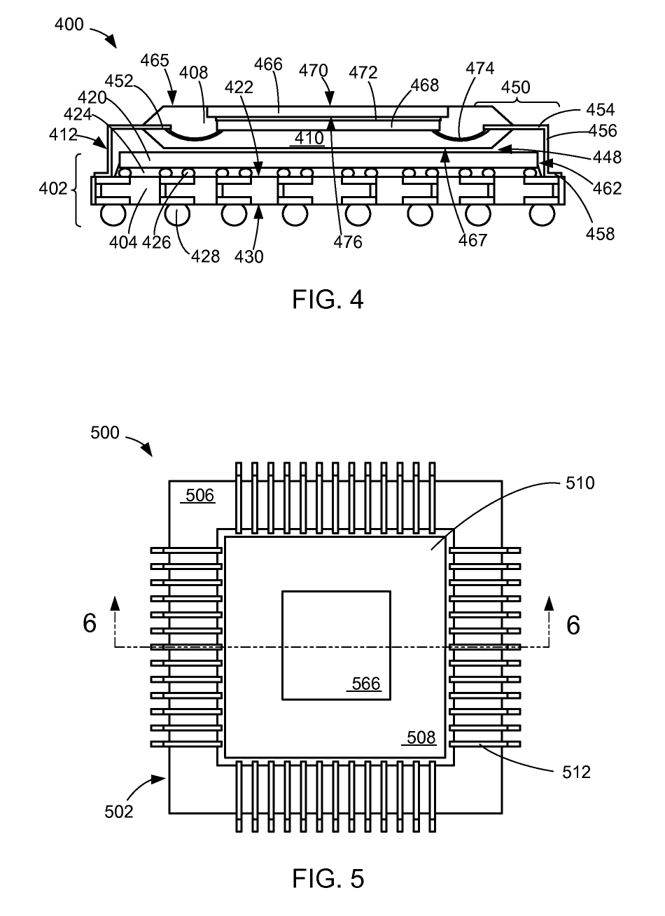

Referring now to FIG. 4, therein is shown a cross-sectional view of an integrated circuit packaging system 400 exemplified along line 2-2 of FIG. 1 in a third embodiment of the present invention. The cross-sectional view depicts a base package 402. The base package 402 is an integrated circuit package. The base package 402 can have a base integrated circuit 420 mounted over a base substrate 404.

The base substrate 404 is a rigid base structure that provides support and connectivity for other components and devices. As an example, the base substrate 404 can be made from conductive material, such as copper or other metals, ceramic material, semi-conducting material, such as silicon, or can be a laminated structure having vias and metal layers (not shown).

The base integrated circuit 420 is a semi-conductor device having active circuitry fabricated thereto. As an example, the base integrated circuit 420 can be a flip chip, an integrated circuit die, a thin integrated circuit die, or an ultrathin integrated circuit die. The base integrated circuit 420 can be mounted over a substrate first side 422 of the base substrate 404.

Base internal interconnects 426 can connect the base integrated circuit 420 and the substrate first side 422. The base internal interconnects 426 are conductive interconnects for electrical interconnection of devices and structures. As an example, the base internal interconnects 426 can be solder balls, solder bumps, or connective bumps. The base internal interconnects 426 can connect the substrate first side and the side of the base integrated circuit 420 facing the substrate first side 422.

A base adhesive 424 can be over the substrate first side 422 and the base integrated circuit 420 can be over the base adhesive 424. The base adhesive 424 is an adhesive material for bonding components, such as an underfill material. As an example, the base adhesive 424 can be a thermally conductive adhesive material, a polymer based adhesive material, or any other adhesive material suitable for bonding components. The base adhesive 424 can surround the base internal interconnects 426.

Base external interconnects 428 can be connected to a substrate second side 430 of the base substrate. The base external interconnects 428 are conductive interconnects for connecting the base substrate 404 to the next system level down (not shown). As an example, the base external interconnects 428 can be solder balls, solder bumps, or conductive bumps. The substrate second side 430 can be the side of the base substrate 404 facing away from the base integrated circuit 420.

A mountable device 408 can be stacked over the base package 402. The mountable device 108 stacked over the base package 402 can form a package-on-package system.

The mountable device 408 can include a mountable encapsulation 410. The mountable encapsulation 410 is a cover, such as a protective cover. As an example, the mountable encapsulation 410 can be formed by molding an encapsulation material such as epoxy molding compound or ceramic material.

The mountable encapsulation 410 can have a mountable first side 465 and a mountable second side 467. The mountable first side 465 can face away from the base integrated circuit 420. The mountable second side 467 can face the base package 402 and can be in contact with the base integrated circuit 420.

A flow channel 448 can be between the mountable second side 467 and the base integrated circuit 420 of the base package 402. The flow channel 448 is a channel for the circulation of air, which can facilitate temperature control for the interface between the mountable device 408 and the base package 402. The flow channel 448 can be between the mountable second side 467 and a portion of the base integrated circuit 420 facing the mountable device 408.

The mountable device 408 can include an interconnect structure 450. The interconnect structure 450 is a partially encapsulated conductive structure for providing electrical connection between internal package components and external components and devices. The interconnect structure 450 is also for providing structural support for suspending a package over other devices or components. As an example, the interconnect structure 450 can be a rigid lead made from conductive materials, such as copper, a copper based alloy, other metallic alloys, or other conductive materials.

The interconnect structure 450 can include internal leads 452 and external leads 412. The internal leads 452 are the portion of the interconnect structure 450 that is encapsulated by the mountable encapsulation 410.

The external leads 412 are conductive connectors for electrically connecting the mountable device 408 to other devices or structures and also provide structural support for suspension of the mountable device 408 over other devices or structures. As an example, the external leads can be a rigid lead made from conductive materials, such as copper, a copper based alloy, other metallic alloys, other conductive materials, of a material that is similar to the interconnect structure 450.

The external leads 412 can be exposed from and extend away from the mountable encapsulation 410. The external leads 412 can connect with the peripheral portion along the perimeter of the base substrate 404 adjacent to the base integrated circuit 420.

The external leads 412 can be exposed from and extend from the mountable encapsulation 410. The external leads 412 can include a lead platform 454, a lead leg 456, and a lead foot 458. The lead platform 454 is the portion of the external leads 412 that is adjacent to the mountable encapsulation 410 and over the base integrated circuit 420.

The lead platform 454 can extend away from the mountable encapsulation 410. The lead platform 454 can extend beyond a base vertical side 462 of the base package 402. The base vertical side 462 is a vertical side of the base package 402. As a specific example, the base vertical side 462 can be the vertical side of the base integrated circuit 420.

The external leads 412 can be bent at the end of the lead platform 454 that is opposite the mountable encapsulation 410 to form the lead leg 456. The lead leg 456 is the portion of the external leads 412 that is adjacent to the base vertical side 462.

As an example, the lead leg 456 can be perpendicular with the lead platform 454 and extend towards the substrate first side 422. As a further example, the lead leg 456 can be parallel with the base vertical side 462. In yet a further example, the lead leg 456 can be perpendicular to the substrate first side 422.

The external leads 412 can be bent at the end of the lead leg 456 opposite the lead platform 454 and adjacent to the substrate first side 422 to form the lead foot 458. The lead foot 458 can extend away from the circuit vertical side 462. The lead foot 458 can be planar with and connected to the substrate first side 422.

The mountable device 408 can include a mountable paddle 466, which is a structure for mounting a device, such as an integrated circuit device. As an example, the mountable paddle 466 can be a die paddle, a die attach paddle, a heat sink, or a combination thereof. The mountable paddle 466 can be made from a number of materials, including conductive material, such as copper, a copper based alloy, other metallic alloys, or other conductive materials.

The mountable paddle 466 can include a paddle first side 470 and a paddle second side 476. The paddle first side 470 can be exposed along the side of the mountable encapsulation 410 facing away from the base package 402. The paddle first side 470 can be co-planar with the side of the mountable encapsulation 410 facing away from the base package 402.

A mountable integrated circuit 468 can be mounted on the paddle second side 476 of the mountable paddle 466. The mountable integrated circuit 468 is a semi-conductor device having active circuitry fabricated thereto. As an example, the base integrated circuit 420 can be an integrated circuit die, a thin integrated circuit die, an ultrathin integrated circuit die, a wire-bonded integrated circuit die, or a flip chip.

A mountable adhesive 472, which is an adhesive material for bonding components, can be on the paddle second side 476 and the mountable integrated circuit 468 can be on the mountable adhesive 472. As an example, the mountable adhesive 472 can be a thermally conductive adhesive material, a polymer based adhesive material, or any other adhesive material suitable for bonding components.

Mountable internal interconnects 474 can connect the mountable integrated circuit 468 and the internal leads 452. The mountable internal interconnects 474 are conductive interconnects for electrical interconnection of devices and structures. As an example, the base internal interconnects 426 can be bond wires or ribbon bond wires.

Referring now to FIG. 5, therein is shown a top view of an integrated circuit packaging system 500 in a fourth embodiment of the present invention. The top view depicts a base package 502. The base package 502 is an integrated circuit package having a side with a recessed interface to receive a matching conformal mating interface of another integrated circuit package. Conformal means that the mating interface of the another integrated circuit package is parallel with the recessed interface.

The base package 502 can include a base encapsulation 506. The base encapsulation 506 is a cover, such as a protective covering. As an example, the base encapsulation 506 can be formed by molding an encapsulation material such as epoxy molding compound or ceramic material.

A mountable device 508 can be over the base package 502. The mountable device 508 is an integrated circuit package having a side with a mating interface to fit within and is conformal with a recess of another integrated circuit package. The mountable device 508 can be over a central portion of the base encapsulation 506. The mountable device 508 stacked over the base package 502 can form a package-on-package system.

The mountable device 508 can have a mountable encapsulation 510. The mountable encapsulation 510 is a cover, such as a protective covering. As an example, the mountable encapsulation 510 can be formed by molding an encapsulation material such as epoxy molding compound or ceramic material.

A mountable paddle 566 can be exposed from the mountable encapsulation 510. The mountable paddle 566 is a structure for mounting a device, such as an integrated circuit device. As an example, the mountable paddle 566 can be a die paddle, a die attach paddle, a heat sink, or a combination thereof. The mountable paddle 566 can be made from a number of materials, including conductive materials, such as copper, a copper based alloy, other metallic alloys, or other conductive materials.

The mountable device 508 can have external leads 512. The external leads 512 are conductive connectors for electrically connecting the mountable device 508 to other devices or structures and also to provide structural support for suspension of the mountable device 508 over other devices or structures. The external leads 512 can be exposed from and extend away from the mountable encapsulation 510. The external leads 512 can extend over the base encapsulation 506.

For illustrative purposes, the integrated circuit packaging system 500 is shown with the external leads 512 along four sides of the mountable device 508, although it is understood that the integrated circuit packaging system 500 can have the external leads 512 arranged differently. For example, the external leads 512 can be only along two opposing sides of the mountable device 508.

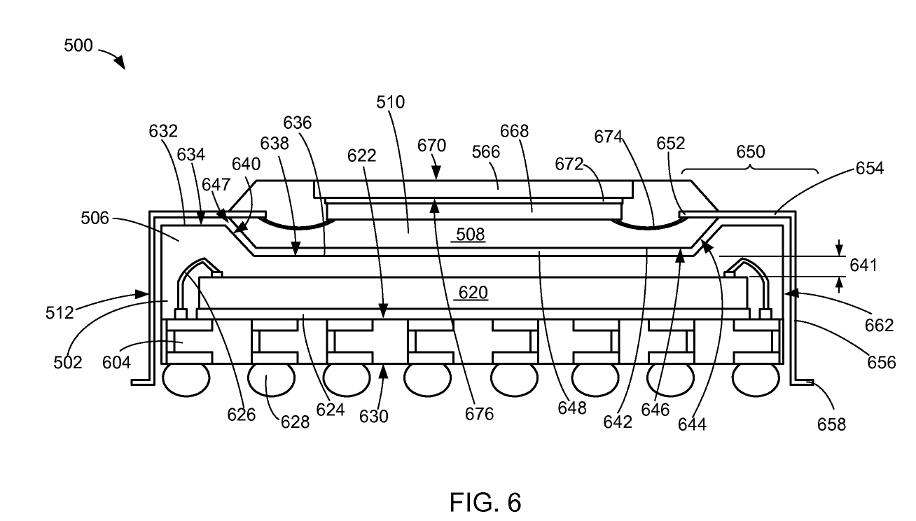

Referring now to FIG. 6, therein is shown a cross-sectional view of the integrated circuit packaging system 500 along line 6-6 of FIG. 5. The cross-sectional view depicts a base integrated circuit 620 mounted over a base substrate 604. The base substrate 604 is a rigid base structure that provides support and connectivity for other components and devices. As an example, the base substrate 604 can be made from conductive material, such as copper or other metals, ceramic material, semi-conducting material, such as silicon, a laminated structure having vias and metal layers (not shown), or a combination thereof.

The base integrated circuit 620 is a semi-conductor device having active circuitry fabricated thereto. As an example, the base integrated circuit 620 can be an integrated circuit die, a thin integrated circuit die, an ultrathin integrated circuit die, or a wire-bonded integrated circuit die. The base integrated circuit 620 can be mounted over a substrate first side 622 of the base substrate 604.

A base adhesive 624 can be over the substrate first side 622 and the base integrated circuit 620 can be over the base adhesive 624. The base adhesive 624 is an adhesive material for bonding components. As an example, the base adhesive 624 can be a thermally conductive adhesive material, a polymer based adhesive material, or any other adhesive material suitable for bonding components.

Base internal interconnects 626 can connect the base integrated circuit 620 and the substrate first side 622. The base internal interconnects 626 are conductive interconnects for electrical interconnection of devices and structures. As an example, the base internal interconnects 626 can be bond wires or ribbon bond wires. The base internal interconnects 626 can be connected to the side of the base integrated circuit 620 facing away from the substrate first side 622.

Base external interconnects 628 can be connected to a substrate second side 630 of the base substrate 604. The base external interconnects 628 are conductive interconnects for connecting the base substrate 604 to the next system level down (not shown). As an example, the base external interconnects 628 can be solder balls, solder bumps, or conductive bumps. The substrate second side 630 can be the side of the base substrate 604 facing away from the base integrated circuit 620.

The base encapsulation 506 can be over and cover the substrate first side 622. The base encapsulation 506 can cover the base integrated circuit 620, the base adhesive 624, and the base internal interconnects 626.

The base encapsulation 506 can include a base shoulder 632 along a base top side 634 of the base encapsulation 506. As a specific example, the portion of the base shoulder 632 along the base top side 634 can have a width of 0.5 millimeters. The base shoulder 632 can be over the base internal interconnects 626. The base shoulder 632 can provide clearance for the base internal interconnects 626 to connect between the substrate first side 622 and the base integrated circuit 620.

The base encapsulation 506 can include a base recess 636 having a recessed surface 638 and a recess side 640. The base recess 636 can be shaped to receive a mating interface of another integrated circuit package.

The base recess 636 can be formed along a central portion of the base top side 634. The base recess 636 can be bounded by the base shoulder 632. The recessed surface 638 can be over the base integrated circuit 620. The horizontal plane of the recessed surface 638 can be below the horizontal plane of the base shoulder 632.

The recess side 640 can be between the recessed surface 638 and the base shoulder 632. The recess side 640 can be sloped and can form an obtuse angle with the recessed surface 638. The recess side 640 can be sloped downward from the base shoulder 632 to the recessed surface 638.

The base encapsulation 506 can include a recess thickness 641, which is measured as the distance between the recessed surface 638 and the side of the base integrated circuit 620 facing away from the substrate first side 622. As a specific example, the recess thickness 641 can have a distance of 150 μm.

The mountable device 508 can be stacked over the base package 502 with a mountable mating interface 642 of the mountable encapsulation 510 in the base recess 636. The mountable mating interface 642 is a surface of the mountable encapsulation 510 configured to fit within and is conformal with a space having matching surface features. The mountable mating interface 642 can be the side of the mountable encapsulation 610 facing the base top side 634 of the base encapsulation 506. The mountable device 508 stacked over the base package 502 can form a package-on-package system.

The mountable mating interface 642 can be conformal with the base recess 636. The mountable mating interface 642 can have a mating side 644 that faces and is parallel to the recess side 640. A mating bottom 646 can be the side of the mountable mating interface 642 that faces and is parallel to the recessed surface 638 of the base recess 636. The mountable mating interface 642 can be conformal with the base recess 636 by having the mating side 644 parallel to the recess side 640 and the mating bottom 646 parallel to the recessed surface 638.

The mountable mating interface 642 can be configured to provide a flow channel 648 between the base recess 636 of the base encapsulation 506 and the mountable mating interface 642. The flow channel 648 is a channel for the circulation of air, which can facilitate temperature control for the interface between the mountable device 508 and the base package 502.

The flow channel 648 can extend from a flow opening 647 between the recess side 640 and the mating side 644, through the space between the mating bottom 646 and the recessed surface 638, to another one of the opening between the recess side 640 and the mating side 644 at the opposite end of the flow channel 648.

The mountable device 508 can include an interconnect structure 650. The interconnect structure 650 is a partially encapsulated conductive structure for providing electrical connection between internal package components and external components and devices. The interconnect structure 650 is also for providing structural support for suspending a package over other devices or components. As an example, the interconnect structure 650 can be a rigid lead made from conductive materials, such as copper, a copper based alloy, other metallic alloys, or other conductive materials.

The interconnect structure 650 can include internal leads 652 and the external leads 512. The internal leads 652 are the portion of the interconnect structure 650 that is encapsulated by the mountable encapsulation 510.

The external leads 512 can be exposed from and extend from the mountable encapsulation 510. The external leads 512 can include a lead platform 654, a lead leg 656, and a lead foot 658. The lead platform 654 is the portion of the external leads 512 that is adjacent to the mountable encapsulation 510 and over the base top side 634 of the base encapsulation 506.

As an example, the lead platform 654 can be parallel with the base shoulder 632, although it is understood that the lead platform 654 may be in a configuration that is not parallel with the base shoulder 632.

The lead platform 654 can extend away from the mountable encapsulation 510. The lead platform 654 can extend beyond a base vertical side 662 of the base package 502. The base vertical side 662 is a vertical side of the base package 502. As a specific example, the base vertical side 662 can be the vertical side of the base encapsulation 506.

The external leads 512 can be bent at the end of the lead platform 654 that is opposite the mountable encapsulation 510 to form the lead leg 656. The lead leg 656 is the portion of the external leads 512 that is adjacent to the base vertical side 662.

As an example, the lead leg 656 can be perpendicular with the lead platform 654 and extend below the horizontal plane of the mating bottom 646. As a further example, the lead leg 656 can be parallel with the base vertical side 662. In yet a further example, the lead leg 656 can extend below the horizontal plane of the substrate second side 630.

The external leads 512 can be bent at the end of the lead leg 656 opposite the lead platform 654 and adjacent to the substrate first side 622 to form the lead foot 658. The lead foot 658 can extend away from the base vertical side 662. The lead foot 658 can be below the horizontal plane of the substrate second side 630. The lead foot 658 can connect to the next system level down (not shown).

The mountable device 508 can include the mountable paddle 566 having a paddle first side 670 and a paddle second side 676. The paddle first side 670 can be exposed along the side of the mountable encapsulation 610 facing away from the base package 502. The paddle first side 670 can be co-planar with the side of the mountable encapsulation 610 facing away from the base package 502.

A mountable integrated circuit 668 can be mounted on the paddle second side 676 of the mountable paddle 566. The mountable integrated circuit 668 is a semi-conductor device having active circuitry fabricated thereto. As an example, the base integrated circuit 620 can be an integrated circuit die, a thin integrated circuit die, an ultrathin integrated circuit die, a wire-bonded integrated circuit die, or a flip chip.

A mountable adhesive 672, which is an adhesive material for bonding components, can be on the paddle second side 676 and the mountable integrated circuit 668 can be on the mountable adhesive 672. As an example, the mountable adhesive 672 can be a thermally conductive adhesive material, a polymer based adhesive material, or any other adhesive material suitable for bonding components.

Mountable internal interconnects 674 can connect the mountable integrated circuit 668 and the internal leads 652. The mountable internal interconnects 674 are conductive interconnects for electrical interconnection of devices and structures. As an example, the base internal interconnects 626 can be bond wires or ribbon bond wires.

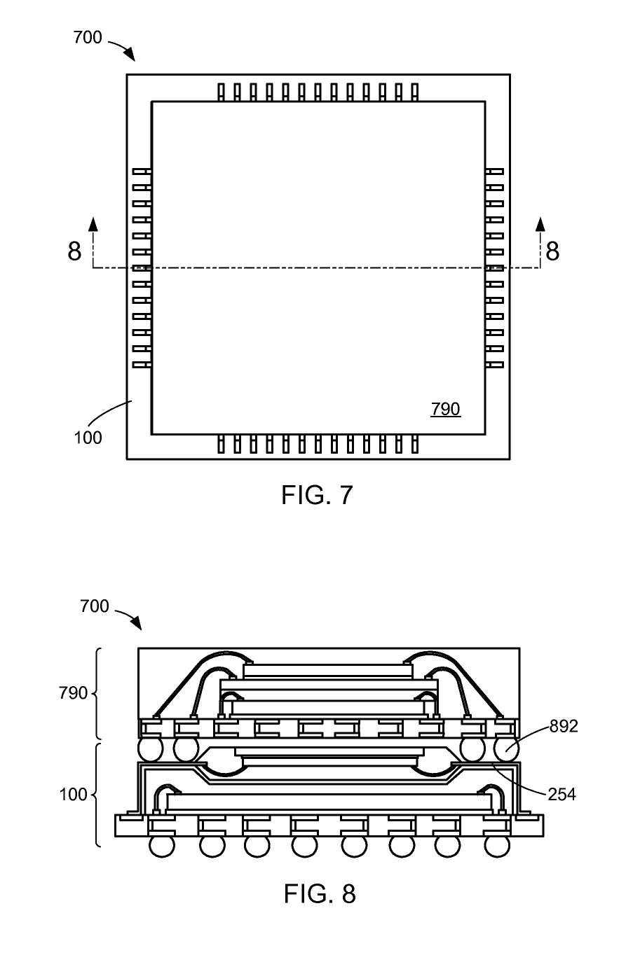

Referring now to FIG. 7, therein is shown a top view of an integrated circuit package-on-package system 700 in a fifth embodiment of the present invention. The top view depicts a top package 790 stacked over the integrated circuit packaging system 100 of FIG. 1.

Referring now to FIG. 8, therein is shown a cross-section view of the integrated circuit package-on-package system 700 along line 8-8 of FIG. 7. The cross-sectional view depicts the top package 790 stacked over the integrated circuit packaging system 100. The top package 790 can be connected to the platform leads 254 of FIG. 2 with top interconnects 892. The top interconnects 892 are conductive interconnects for connecting the top package 790 to other devices and components. As an example, the top interconnects 892 can be solder balls, solder bumps, or conductive bumps.

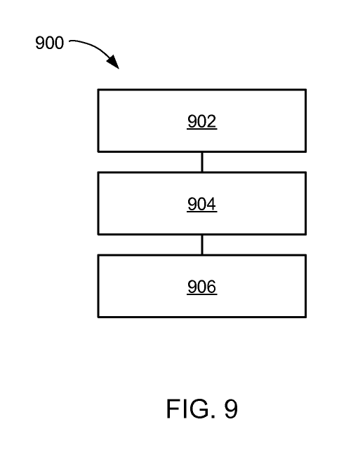

Referring now to FIG. 9, therein is shown a flow chart of a method 900 of manufacture of an integrated circuit packaging system in an embodiment of the present invention. The method 900 includes: forming a base package having a base integrated circuit over a base substrate in a block 902; stacking a mountable device over the base package with a flow channel between the mountable device and the base package in a block 904; and forming an external lead having a lead platform and a lead leg, the lead platform extending from the mountable device and the lead leg parallel to the base package in a block 906.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems/fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
forming a base package having a base integrated circuit over a base substrate;
stacking a mountable device over the base package with a flow channel between the mountable device and the base package; and
forming an external lead having a lead platform and a lead leg, the lead platform extending from the mountable device and the lead leg parallel to the base package.

2. The method as claimed in claim 1 wherein:
forming the base package includes forming a base encapsulation having a base recess; and
stacking the mountable device includes stacking the mountable device over the base encapsulation and in the base recess.

3. The method as claimed in claim 1 wherein stacking the mountable device includes stacking the mountable device having a mountable integrated circuit and a mountable paddle, the mountable integrated circuit mounted over the mountable paddle.

4. The method as claimed in claim 1 wherein stacking the mountable device includes stacking the mountable device with the external lead extending below a horizontal plane of the base substrate.

5. The method as claimed in claim 1 wherein stacking the mountable device includes stacking the mountable device having a mountable paddle exposed along a side of the mountable encapsulation facing away from the base package.

6. A method of manufacture of an integrated circuit packaging system comprising:
forming a base package having a base integrated circuit over a base substrate;
stacking a mountable device, having a mountable encapsulation, over the base package with a flow channel between the mountable encapsulation and the base package; and
forming an external lead having a lead platform and a lead leg, the lead platform extending from the mountable device and over the base package and the lead leg parallel to the base package.

7. The method as claimed in claim 6 further comprising stacking a top package over the mountable device and connected to the lead platform.

8. The method as claimed in claim 6 wherein stacking the mountable device includes stacking the mountable device with the external lead connected to the base substrate.

9. The method as claimed in claim 6 wherein forming the base package includes forming the base package having a base encapsulation including a base recess bounded by a base shoulder.

10. The method as claimed in claim 6 further comprising:
a base circuit device mounted over the base substrate; and
wherein:
the base integrated circuit is mounted over the base circuit device.

11. An integrated circuit packaging system comprising:
a base package having a base integrated circuit over a base substrate;
a mountable device stacked over the base package with a flow channel between the mountable device and the base package; and
an external lead having a lead platform and a lead leg, the lead platform extending from the mountable device and the lead leg parallel to the base package.

12. The system as claimed in claim 11 wherein:
the base package includes a base encapsulation having a base recess; and
the mountable device includes the mountable device over the base encapsulation and in the base recess.

13. The system as claimed in claim 11 wherein the mountable device includes a mountable integrated circuit and a mountable paddle, the mountable integrated circuit mounted over the mountable paddle.

14. The system as claimed in claim 11 wherein the lead leg of the external lead extends below a horizontal plane of the base substrate.

15. The system as claimed in claim 11 wherein the mountable device includes a mountable paddle exposed along a side of the mountable encapsulation facing away from the base package.

16. The system as claimed in claim 11 wherein:
the mountable device includes a mountable encapsulation with the flow channel between the mountable encapsulation and the base package; and
the lead platform of the external lead is over the base package.

17. The system as claimed in claim 16 further comprising a top package stacked over the mountable device and connected to the lead platform.

18. The system as claimed in claim 16 wherein the external lead is connected to the base substrate.

19. The system as claimed in claim 16 wherein the base package includes a base encapsulation having a base recess bounded by a base shoulder.

20. The system as claimed in claim 16 further comprising:
a base circuit device mounted over the base substrate; and
wherein:
the base integrated circuit is mounted over the base circuit device.
